(19) United States
(12) Patent Application Publication
(10) Pub. No.: US 2005/0022743 A1
(43) Pub. Date: Feb. 3, 2005

(54) Evaporation container and vapor deposition apparatus

(75) Inventors: Junichiro Sakata, Atsugi (JP); Yasuo Nakamura, Machida (JP); Yutaka Okazaki, Atsugi (JP)

Correspondence Address: NIXON PEABODY, LLP, 401 9TH STREET, NW, SUITE 900, WASHINGTON, DC, 20004-2128, US

(73) Assignee: Semiconductor Energy Laboratory Co., Ltd., Atsugi-shi (JP)

(21) Appl. No.: 10/900,387

(22) Filed: Jul. 28, 2004

(30) Foreign Application Priority Data
May 21, 2004 (JP) 2004-152603
Jul. 31, 2003 (JP) 2003-283781

(51) Int. Cl. C23C 16/00

(52) U.S. Cl. 118/726

(57) ABSTRACT

To provide an evaporation container and a vapor deposition apparatus in which vapor deposition can be performed stably with use of an evaporation container formed of an inexpensive material being easily processed without clogging the material. The side surface of a lid for the evaporation container is provided with an accordion-shaped structure. The lid of the evaporation container is made larger than an opening of an evaporation source such that the lid is directly contacted to a heating portion. According to the structure, the periphery of the opening for the lid is not easily cooled down; and therefore the variation in temperature between the body and the lid of the container is hardly generated. Consequently, an evaporated material hardly clog at the opening, vapor deposition can be stably performed for a long time, thereby increasing productivity.

### BACKGROUND OF THE INVENTION

1. Field of the Invention

The present invention relates to a manufacturing device comprising a film formation device used for forming a film formed of a material, which can be deposited by vapor deposition (hereinafter referred to as an evaporation material).

2. Description of the Related Art

In recent years, research related to a light-emitting device having an electroluminescence element (hereinafter referred to as an EL element) as a self-luminous light-emitting element has been activated. The light-emitting device is also referred to as an organic EL display or an organic light-emitting diode. Since these light-emitting devices have such characteristics as rapid response speed that is suitable for a moving picture display, low voltage, low power consumption driving, they have been attracting attention for next generation displays including new-generation cellular phones and personal digital assistants (PDAs).

The EL element utilizing a layer including an organic compound as a light-emitting layer has a structure in which the layer including the organic compound (hereinafter referred to as an EL layer) is sandwiched between an anode and a cathode. The EL element emits light as follows. Upon applying an electric field to the anode and cathode, holes and electrons are recombined with each other in the EL layer to generate excitons, and an energy gap returning to the ground state from the excited state is emitted as photon. Luminescence obtained from the EL element includes luminescence generated in returning to a base state from an excited singlet state (fluorescence) and luminescence generated in returning to a base state from an excited triplet state (phosphorescence).

The EL layer has a laminated structure represented by a laminated structure in which a hole transporting layer, a light emitting layer, and an electron transporting layer are sequentially laminated. Materials for forming the EL layer are broadly classified into a low molecular weight (monomer) material and a high molecular weight (polymer) material. The low molecular weight material is generally formed by using a vapor deposition apparatus.

The conventional vapor deposition apparatus comprises a substrate holder for installing a substrate, a container (or an evaporation boat) filled with an EL material, i.e. the evaporation material, a shutter for preventing the sublimating material from sublimating, and a heater for heating the EL material inside the container. The EL material heated by the heater is sublimated and deposited over a rotating substrate. At this moment, in order to deposit the EL material over the substrate uniformly, the substrate is kept 1 m or more away from the container filled with the evaporation material.

According to the conventional vapor deposition apparatus and conventional evaporation method, when an EL layer is formed by vapor deposition, the sublimated EL material is mostly adhered to an inner wall, a shutter, and a prevention shield against adhesion (a protective plate for preventing an evaporation material from adhering to an inner wall of a film formation chamber) inside of the film formation chamber for the vapor deposition apparatus. Therefore, in forming the EL layer, the efficiency in utilizing expensive EL materials is extremely low, i.e. about 1% or less, and manufacturing cost of a light emitting device becomes very high.

In the conventional vapor deposition apparatus, in order to form a film with uniform thickness, it is necessary to keep the substrate 1 m or more away from an evaporation source. Therefore, the vapor deposition apparatus grows in size, a period required for exhausting each film formation chamber of the vapor deposition apparatus is prolonged; therefore, film formation speed is reduced and throughput is degraded. Also, in the case of using a large-size substrate, the film thickness is easily varied in a center portion and a peripheral portion of one substrate. Furthermore, since the vapor deposition apparatus has a structure in which vapor deposition is carried out by rotating a substrate, there is a limitation in the vapor deposition apparatus which handles a large-size substrate.

In view of the above-described problems, the present inventor has proposed a novel vapor deposition apparatus (patent document 1, and patent document 2). Patent Document 1: Japanese Patent Laid-Open No. 2001-247959 Patent Document 2: Japanese Patent Laid-Open No. 2002-60926

A large quantity of evaporation material is required for a large-size substrate. In the case of forming a large-size substrate with not less than 1 m on a side, if a small-size container is used, the container runs out of the evaporation material quickly. Therefore, the number of containers must be increased so as to replace the containers, frequently. However, it takes a long time for forming the large-size substrate, and therefore, the container is likely to run out of the EL material during vapor deposition. Further, the heating period is prolonged to excess, thereby degrading throughput. Accordingly, in order to evaporate the large-size substrate for a long time, it is necessary to use a large-size container.

In order to replace the container installed in the evaporation source with the other container easily, the upper portion of the evaporation source is needed to be opened. Further, since it is necessary to provide a space for taking the container out of the device from between the container and a heating portion, the heating portion is not in contact with the container. Accordingly, as for a method of heating the container, the container is mainly heated by radiant heat. However, since the upper portion of the container is opened, radiant heat leaks easily; and therefore the upper portion of the container is not easily heated. Consequently, a problem arose as follows. The temperature varies between the upper and lower portions of the container, an evaporated material is cooled at the upper portion of the container, and the cooled material clogs the opening. In particular, an evaporation material having a high evaporation temperature is likely to generate the different in temperature and is difficulty evacuated.

### SUMMARY OF THE INVENTION

It is an object of the present invention to provide a manufacturing device handling vapor deposition, which exhibits stable vapor deposition with superior throughput by utilizing radiation heat generated in an evaporation source efficiently.

According to one aspect of the present invention, a film formation device for vapor depositing a material evaporated by heating an evaporation source over a substrate, the evaporation source comprising: a heating portion; and a container including a hollow to be filled with the material, wherein a side surface of an upper portion for the container is provided with an accordion-shaped structure.

According to the invention, since the upper portion of the container comprises the accordion-shaped structure, the surface area of the side surface of the upper portion thereof is increased as compared with a container which does not has the accordion-shaped structure. Consequently, the radiant heat absorption is increased in the upper portion of the container, and the upper portion thereof is not easily cooled down. As a result, the opening of the container is hardly clogged with the material.

According to another aspect of the present invention, in a film formation device for vapor depositing a material evaporated by heating an evaporation source over a substrate, the evaporation source comprising: a heating portion; and a container including a hollow to be filled with the material, wherein an upper portion of the side surface for the container is coated with a material having a higher absorptance of radiant heat than that of a material constituting the container.

According to the invention, since the upper portion of the side surface for the container is coated with the material having higher absorptance of radiant heat than that of the material constituting the container, the radiant heat absorptance of the upper portion for the container is also increased. Also, since the container and the coating film are contacted to each other, the thermal conductivity of the container is improved as compared with the case of heating by radiant heat. Therefore, the upper portion of the container can be effectively heated, the variation in temperature between upper and lower portion of the container is eliminated, which prevents the opening from being clogged with the material.

According to another aspect of the invention, in a film formation device for vapor depositing a material evaporated by heating an evaporation source over a substrate, the evaporation source comprising: a heating portion; and a container including a hollow to be filled with the material, wherein an upper portion of the side surface for the container is coated with a material having a higher reflectivity of radiant heat than that of a material constituting the container.

According to the present invention, when the upper portion of the side surface for the container is coated with the material having the higher reflectivity of radiant heat than that of the material constituting the container, the radiant heat from the heating portion is reflected by the container, thereby preventing decline in temperature of the heating portion. Therefore, vapor deposition can be carried out at a stable temperature.

According to another aspect of the invention, in a film formation device for vapor depositing a material evaporated by heating an evaporation source over a substrate, the evaporation source comprising: a heating portion; and a container including a hollow to be filled with the material, wherein an upper portion of the side surface for the container is provided with an accordion-shaped structure, and the upper portion of the side surface thereof is coated with a material having a higher absorptance or reflectivity of radiant heat than that of a material constituting the container.

According to the present invention, since the upper portion of the container comprises the accordion-shaped structure and is coated with a coating film, the upper portion thereof can be effectively heated. Furthermore, it is possible to prevent the temperature of the heating portion from decreasing, and hence, vapor deposition can be stably performed with the manufacturing device having superior temperature control.

According to another aspect of the invention, in a film formation device for vapor depositing a material evaporated by heating an evaporation source over a substrate, the film formation device comprising: a mechanism for replacing a first container installed in the evaporation source with another second container, wherein a film formation is carried out by heating the evaporation source.

According to the present invention, the container can be heated without clogging the material at the opening of the upper portion for the container even if the top of the evaporation source is opened. Therefore, it is possible to replace the first container, which runs out of the material due to heating, with the second container filled with the material. Thus, the material can be supplied by replacing the container without exposure to the atmospheric air, vapor deposition can be stably carried out for a long time, thereby providing a manufacturing device with high throughput.

The invention further comprises a structure as follows.

A container of the invention has a structure in which an outer edge of the upper potion for the container (hereinafter referred to as a lid) widely protrudes outwardly beyond an opening of the evaporation source such that the lid is in contact with the heating portion of the evaporation source. According to the structure, heat generated in the heating portion is conducted to the lid from the heating portion, which allows the container to maintain high temperature easily. Preferably, the lid of the container is formed of a material having a high thermal conductivity so as to transmit heat effectively from the heating portion. The vapor deposition apparatus having an above-descried crucible can suppress the variation in temperature of the crucible, thereby carrying out stable vapor deposition for a long time.

According to another aspect of the invention, in a film formation device for vapor depositing a material evaporated by heating an evaporation source over a substrate, the evaporation source comprising: a heating portion; a container filled with a material to be evaporated; and a space for installing the container, wherein the heating portion is arranged around the space, and an outer edge of a lid for the container protrudes outwardly from a body of the container so as to be larger than an opening of the evaporation source and to be in contact with the heating portion.

According to the present invention, the lid of the container protrudes outwardly like eaves, which is directly in contact with the heating portion; and therefore, the upper portion of the container is directly heated not only by radiant heat but also by the heating portion. Further, heat is directly conducted to the container body from the lid of the container. By utilizing the structure of the container, the variation in temperature between the lid and the body of the container is reduced, thereby preventing the opening from being clogged with the material.

According to another aspect of the invention, in a film formation device for vapor depositing a material evaporated by heating an evaporation source over a substrate, the evaporation source comprising: a heating portion; a container filled with a material to be evaporated; and a space for installing the container, wherein an outer edge of a lid for the container protrudes outwardly from an opening of the evaporation source so as to be in contact with the heating portion, and the outer edge of the lid is coated with a material having a higher thermal conductivity than that of a material constituting the lid of the container.

According to the present invention, the outer edge of the lid is coated with the material having the higher thermal conductivity than that of the material constituting the lid of the container, and therefore the lid of the container can conduct heat well from the heating portion. Further, the container body is in contact with a coating film, which coats the lid of the container, and hence, the container body is efficiently heated. By utilizing the structure, the variation in temperature between the lid and the body of the container is reduced, thereby preventing the opening from being clogged with the material.

According to the above-mentioned structures, it is possible to prevent the opening from being clogged with the evaporation material, which is caused by low temperature in the lid of the container, especially, in the periphery of the opening for the lid. Even in the case of using a vapor deposition apparatus with a detachable evaporation source, the evaporation rate can be stabilized and the volume of an evaporation container can be enlarged, which results in a stable product quality, and improved throughput at a low price.

With respect to the above-described structure, the lid and body of the container may be formed of a material having a higher thermal conductivity. Preferably, in consideration of the reactivity and workability to the temperature and the evaporation material to be used etc., each of the lid and body for the container is appropriately formed of one or more material selected from gold; silver; platinum; copper; aluminum; nickel; beryllium; silicon carbide; carbon nitride; boron nitride; silicon oxide; beryllium oxide; and aluminum nitride, which are substances having high thermal conductivity.

In the foregoing structures, it is preferable that the lid of the container be formed of a same material as that of the conventional evaporation container, and the outer edge of the lid to be coated with the coating film be formed of one or more material selected from gold; silver; platinum; copper; aluminum; nickel; beryllium; silicon carbide; carbon nitride; boron nitride; silicon oxide; beryllium oxide; and aluminum nitride; which are substances having high thermal conductivity, in consideration of the reactivity, workability, and thermal expansion coefficient to the temperature and the evaporation material to be used etc.

According to the manufacturing device of the invention, in the film formation steps for vapor deposition, the container filled with the evaporation material can be prevented from being clogged with the material by heating the upper portion of the container to be filled with the evaporation material, i.e. by heating the lid of the container. Furthermore, vapor deposition can be stably carried out for a long time, thereby providing a manufacturing device with superior throughput.

### BRIEF DESCRIPTION OF THE DRAWINGS

In the accompanying drawings:

FIG. 1 is a diagram showing an example of a structure for a container according to the present invention;

FIG. 2 is a diagram showing an example of a structure for a container according to the present invention;

FIG. 3 is a diagram showing a vapor deposition apparatus using the container according to the present invention;

FIGS. 4A and 4B are diagrams showing the container and a method for heating the same according to the present invention;

FIGS. 5A and 5B are diagrams showing an example of the structure for the container according to the present invention;

FIGS. 6A and 6B are diagrams showing an example of the container according to the present invention;

FIGS. 7A and 7B are diagrams showing a vapor deposition apparatus using the container according to the present invention;

FIG. 8 is a diagram showing a vapor deposition apparatus using the container according to the present invention;

FIG. 9 is a diagram showing an example of a light emitting device using the container and the vapor deposition apparatus according to the present invention;

FIG. 10 is a diagram showing an example of a light emitting device using the container and the vapor deposition apparatus according to the present invention; and

FIGS. 11A to 11E are diagrams showing electric appliances applied with the present invention.

### DETAILED DESCRIPTION OF THE INVENTION

Embodiment Mode 1

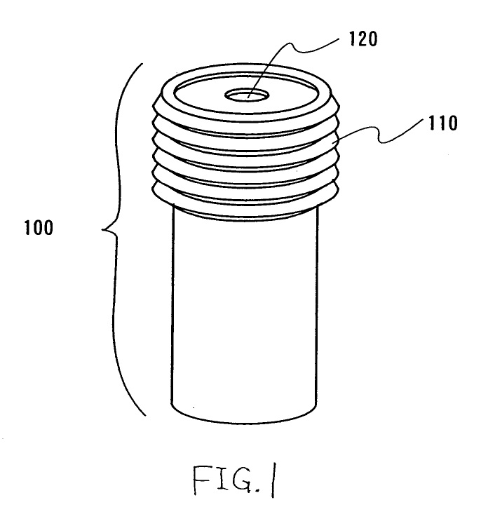

FIG. 1 shows a perspective view of a container 100 for the manufacturing device according to the present invention. The interior of the container 100 is hollow, and is filled with an evaporation material required for an organic EL element such as copper phthalocyanine (abbreviated as CuPc); 4,4′-bis-[N-(naphthyl)-N-phenyl-amino]-biphenyl (abbreviated as α-NPD); tris-8-quinolinolate aluminum complex (abbreviated as Alq₃); and lithium fluoride (LiF). An accordion-shaped portion 110 including an accordion-shaped structure is provided at an upper portion of a side surface for the container 100, and an opening 120 for scattering evaporation particles is formed on a top surface of the container.

A material for the container 100 may be arbitrarily selected from materials as follows: tantalum; molybdenum; tungsten; titanium; boron nitride; more preferably, gold; silver; platinum; copper; aluminum; nickel; beryllium; silicon carbide; silicon nitride; boron nitride; silicon oxide; beryllium oxide; aluminum nitride; and the like. The thickness of the container may be determined in consideration of the amount, the form, the thermal conductivity of the evaporation material and the like.

The opening portion 120 may be partly formed on the top surface of the container. Alternatively, the opening may be formed on the entire surface of the top surface.

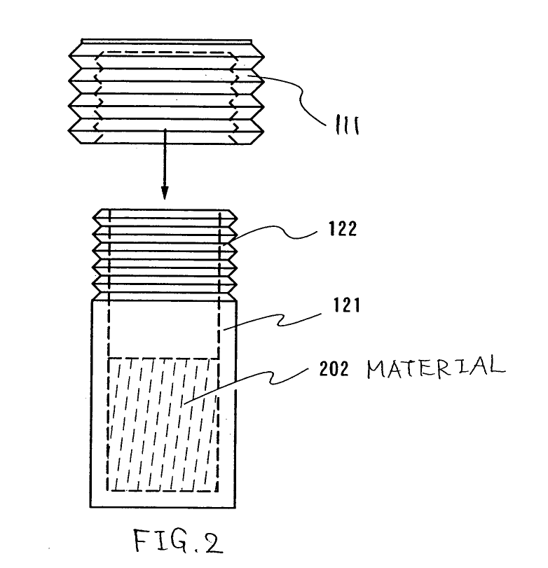

The container 100 may be separated into an upper part and a lower part. In FIG. 2, the container 100 is composed of the upper part 111 and the lower part 121, wherein the upper part serves as a lid for the lower part. As shown in FIG. 2, the side surface of the upper part 111 is provided with the accordion-shaped structure, and the upper part is screwed in the lower part at a screw unit 122. Rather than providing the screw unit, the upper part may be fitted into the lower part by covering the lower part with the upper part. Not illustrated in the drawings, in order to prevent a material inside the container from suddenly boiling, an inner lid may be additionally provided between the upper and lower parts.

The projections of the accordion-shaped portion may be identical with the thickness of the side wall of the container, or may be protruded outwardly therefrom.

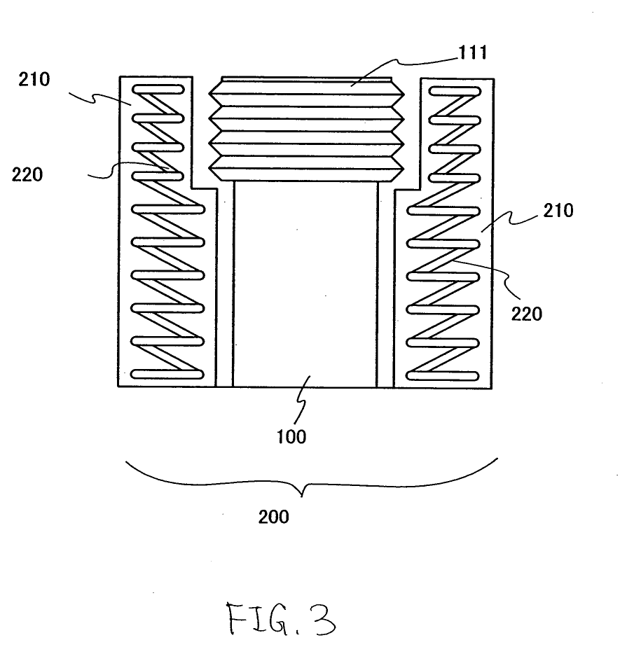

FIG. 3 shows a state in which the container 100 is set in an evaporation source 200. The evaporation source 200 is provided with a heating portion 210, and the interior thereof can be heated with a heater 220. Note that the invention is not limited to this mechanism. Upon vapor deposition, the heating portion 210 is heated so as to heat the container by radiant heat.

It is preferable that the surface of the accordion-shaped portion 110 be coated with a black material such as carbon black, and ceramic which easily absorb radiant heat. In this case, since the absorptance of radiant heat for the upper part of the container is higher than that of the lower part, the upper part of the container absorbs radiant heat efficiently and conducts heat to the container; therefore the variation in temperature is hardly generated between the upper and lower parts of the container. As a result, it is possible to prevent the opening from being clogged with the material.

Preferably, the surface of the accordion-shaped portion 110 is coated with a material having higher absorptance of radiant heat than that of the material for constituting the container. When the container is formed of titanium, for example, the surface of the accordion-shaped portion is preferably coated with a metal film such as silver; gold; platinum; aluminum; copper; nickel; beryllium; silicon carbide; carbon nitride; silicon nitride; boron nitride; silicon oxide; beryllium oxide; and aluminum oxide. In this case, the metal film serves as a film for reflecting radiant heat while absorbing radiant heat. Therefore, radiant heat generated from the heater is reflected by the metal film, and the heater is heated again with the reflected radiant heat so as to prevent the temperature of the heater from decreasing. In addition, the metal film also absorbs heat itself so as to conduct the absorbed heat to the container in contact with the metal film. Thus, the upper portion of the container can be efficiently heated with the radiant heat, the temperature of the evaporation source becomes stable, the variation in temperature is reduced between the upper and lower parts of the container, thereby preventing the material from closing at the opening.

Note that the clogged opening can be prevented even if the upper part of the container is not provided with the accordion-shaped structure and is only coated with a film for absorbing radiant heat or a film for reflecting radiant heat. Accordingly, concerning the structure of the upper part of the container, the container for the evaporation source may be formed by properly combining the accordion-shaped structure, the film for absorbing radiation film, and the film for reflecting radiation film.

By utilizing the above-descried container, the variation in temperature can be reduced between the upper and lower parts of the container and vapor deposition can be carried out without clogging the material at the opening of the container even if the evaporation material with higher evaporation temperature is filled in the container. As a result, a manufacturing device with high productivity in which vapor deposition can be carried out for a long time can be provided.

Embodiment Mode 2

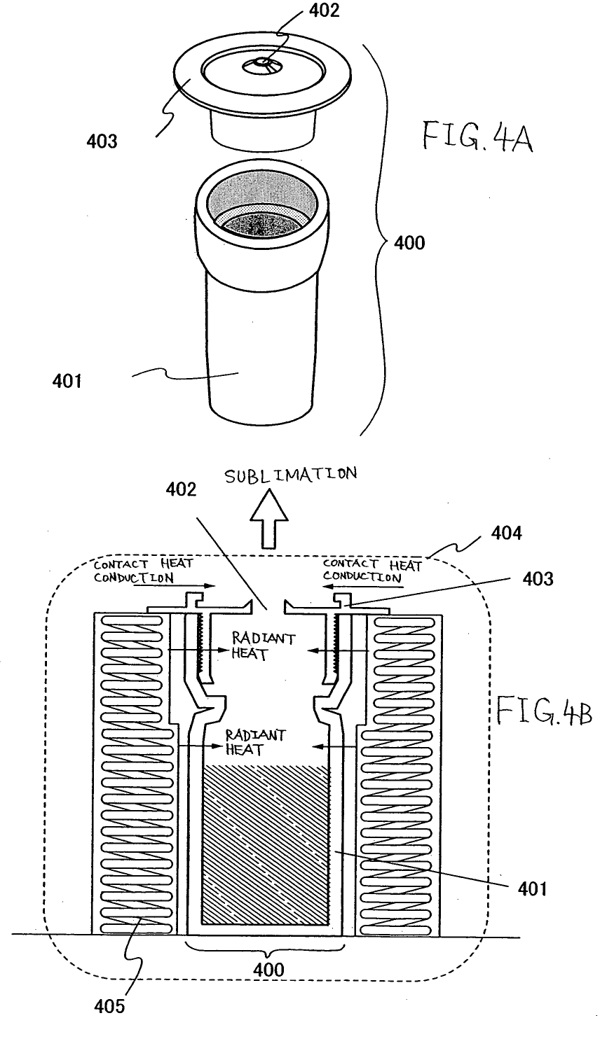

FIG. 4A shows an overall view of an evaporation container 400 relating to the manufacturing device according to the invention. The evaporation container 400 is composed of a cylindrical body 401 with a bottom (a portion filled with an evaporation material), and a lid 403 including an opening 402. The interior of the container 400 is hollow, and is filled with an evaporation material required for an electroluminescence element such as copper phthalocyanine (abbreviated as CuPc); 4,4′-bis-[N-(naphthyl)-N-phenyl-amino]-biphenyl (abbreviated as 8-NPD); tris-8-quinolinolate aluminum complex (abbreviated as Alq₃); lithium fluoride (LiF); and molybdenum oxide (abbreviated as MoOₓ). Vapor deposition is performed by using an evaporation source filled with a desired material in accordance with a layer to be vapor deposited.

FIG. 4B shows a state in which the container 400 is set in the evaporation source 404. The evaporation source is provided with a heating portion. Although a mechanism for heating the container with a heater 405 is illustrated in FIG. 4B, the present invention is not limited thereto.

As shown in FIG. 4B, the lid 403 is formed so as to be larger than the diameter of the opening for the evaporation source 404. Upon using the lid 403, the lid is set so as to be in contact with the heating portion directly. This allows the lid 403 to be heated by thermal conduction, directly. Therefore, heat can be efficiently conducted to the lid 403 from the heater, thereby maintaining high temperature in comparison with the case of using radiant heat. At the same time, the body 401 is heated with radiant heat generated in the heater 420.

As set forth above, the lid 403 is effectively heated, which conducts heat to the body 401. The variation in temperature between the body 401 and the lid 403 is hardly generated, which prevents the material from clogging at the opening. Further, the lid 403 is easily opened, and hence, the opening 402 for the lid is made larger than that of the conventional one. As a result, it is possible to prevent the material from clogging at the opening.

It is preferable that a material for the container 400 be arbitrarily selected from materials as follows: tantalum; molybdenum; tungsten; titanium; boron nitride; more preferably, gold; silver; platinum; copper; aluminum; nickel; beryllium; silicon carbide; silicon nitride; boron nitride; silicon oxide; beryllium oxide; aluminum nitride, which are substances having higher thermal conductivity. The thickness of the container 400 may be determined in consideration of the quantity, the form, and the thermal conductivity of the evaporation material, etc.

The lid 403 may be formed of a material having superior thermal conductivity. More specifically, the lid 403 may be formed of the conventional material such as titanium and ceramic. Then, the surface of the lid may be coated with a metal material having superior thermal conductivity such as gold; silver; platinum; copper; aluminum; nickel; beryllium; silicon carbide; carbon nitride; silicon nitride; boron nitride; silicon oxide; beryllium oxide; and aluminum nitride. In such case, it is preferable that the material for the lid be appropriately selected in consideration of each thermal expansion coefficient of a material to be coated, a material for coating the lid, and the body 401.

In addition, the surface of the body 401 may be coated with a black material such as carbon black, and ceramic which easily absorb radiant heat. This allows the body 401 to absorb radiant heat efficiently such that the variation in temperature between the body 401 and the lid 403 is reduced.

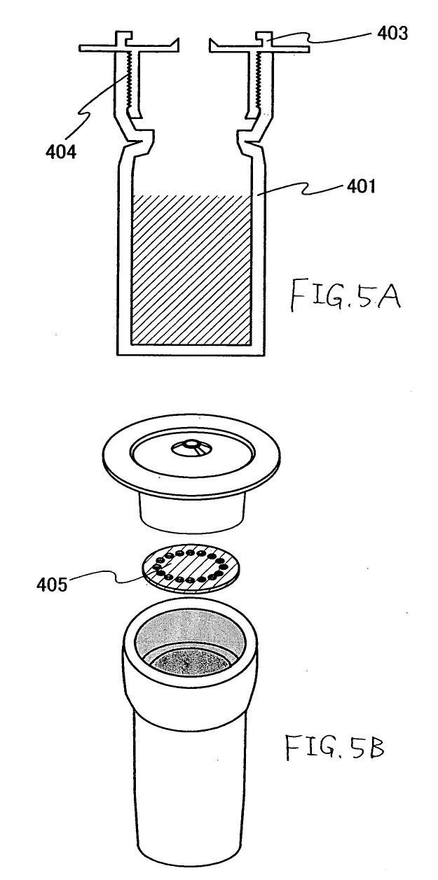

Meanwhile, a cross sectional view of the container 400 is depicted in FIG. 5A. The lid 403 is screwed in the body 401 of the evaporation container at the screw unit 404 in the drawing. Further, the lid 403 may be fitted into the body 401 by covering the body with the lid, rather than providing the screw unit. As illustrated in FIG. 5B, in order to prevent the material from suddenly boiling, an inner lid 405 may be additionally provided between the lid and the body.

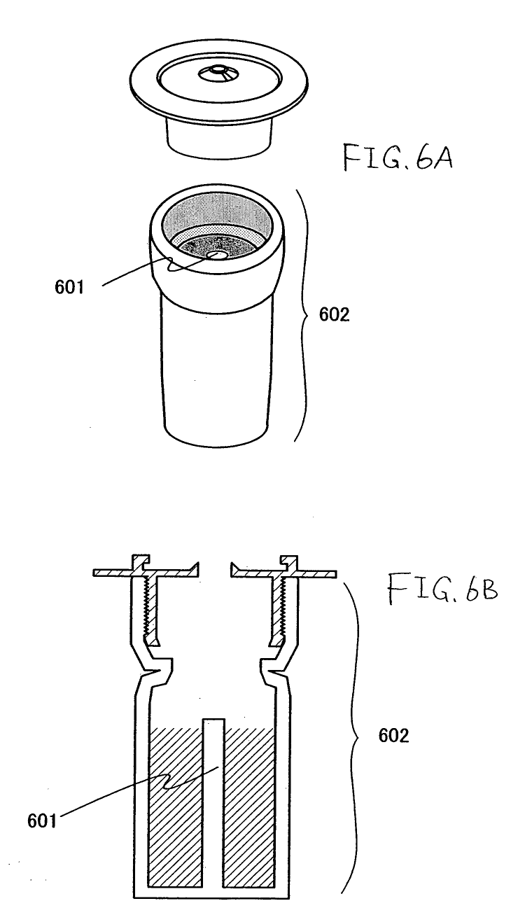

As for the other structure for the container as illustrated in FIGS. 6A and 6B, in the case of using a body 602 having a structure in which a metal rod 601 in contact with the bottom surface of the body is provided at the center of the bottom thereof, the evaporation material is uniformly heated in the center portion and peripheral portion of the body 602. Particularly, the body 602 is effective in the case where the evaporation material has high sublimation temperature, or in the case where mass of the evaporation material is filled in the container.

According to the manufacturing device using the foregoing container, even if the evaporation material with high evaporation temperature is filled in the container, the variation in temperature between the upper and lower parts of the container can be reduced, vapor deposition can be carried out for a long time while preventing the material from clogging at the opening of the container, thereby providing the manufacturing device with high productivity.

Embodiment Mode 3

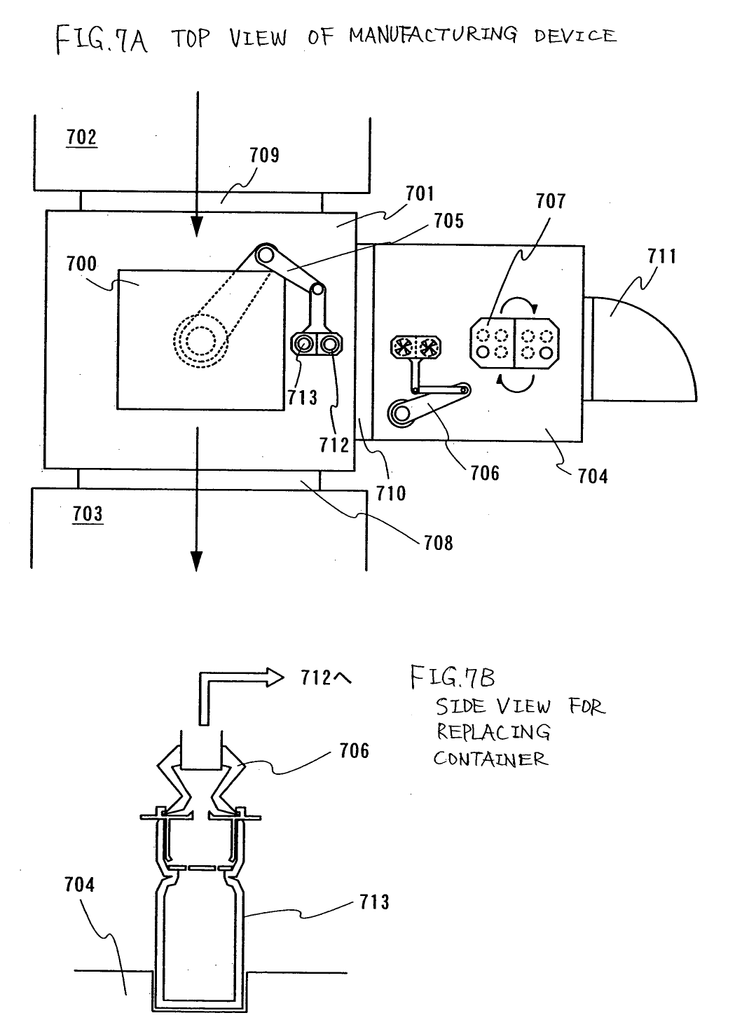

FIGS. 7A to 7B are top views of a manufacturing device according to the present invention.

In FIG. 7A, reference numeral 700 denotes a substrate; 701, a film formation chamber; 702 or 703, a transporting chamber; 704, a container installation chamber; 705, an evaporation-source-driving robot; 706, a container transporting robot; 707, a container setting turntable; 708, 709, or 710, a shutter for dividing each chamber; and 711, a door.

The substrate 700 is transported from the transporting chamber 702 into the film formation chamber 701. In the case of vapor depositing selectively, an alignment of an evaporation mask to the substrate is performed prior to vapor deposition.

In the evaporation source 712, two containers 713 filled with an EL material are provided. Note that sliding shutters (not shown) are provided for upper portions of each container. FIG. 7A shows an example in which one evaporation source comprises two containers. However, three or more containers may also be provided in the evaporation source, and the invention is not exclusively limited to the structure of FIG. 7A. The two containers may be filled with the same material, or filled with different materials such as a host material, and a dopant material, respectively.

When the containers 713 set in the evaporation source 712 are heated to the evaporation temperature or more, evaporation particles jump out of each opening of the upper portions for the containers. Then, the device is kept to a predetermined film formation rate. According to the invention, since each upper portion of the containers is difficult to be cooled down, the openings are hardly clogged with the evaporation material even if the evaporation source 712 is opened. Therefore, a stable film formation rate can be obtained. After stabilizing the device to the predetermined film formation rate, a substrate shutter (not shown) is opened to carry out vapor deposition over the substrate by driving the evaporation-source-driving robot 705, which transports the evaporation source 712. By moving the evaporation source back and forth repeatedly, a film is uniformly formed over the substrate 700. After the vapor deposition, the substrate shutter is closed, and then the evaporated substrate 700 is transported into the transporting chamber 703. By performing the vapor deposition repeatedly, the EL material can be deposited over mass of substrates.

Further, a mechanism for replacing the containers set in the evaporation source 712 with the other containers is provided in the manufacturing device of FIG. 7A. A procedure for replacing the containers is described below with reference to FIG. 7B.

The container installation chamber 704 is vented so as to maintain an atmospheric pressure. At this moment, since the shutter 710 is closed, the transporting chamber 701 is kept in vacuum. The door 711 is opened, and the containers 713 filled with the EL material are set to the container setting turntable 707. Thereafter, the door 711 is closed, and the container installation chamber 704 is evacuated to the vacuum level equal to or lower than that of the transporting chamber. Since the volume of the container installation chamber 704 is smaller than that of the film formation chamber 701, it is possible to reduce the chamber pressure to the predetermined level at short times. When the predetermined vacuum level is reached, the shutter 710 is opened, the first containers set in the evaporation source 712 are taken out of the film formation chamber to set in the container setting turntable 707 by driving the container transporting robot 706. The container setting turntable 707 is rotated, and second containers filled with the EL material are taken out to set in the evaporation source 712 newly.

The transporting mechanism of the invention is not limited to the mechanism as illustrated in FIG. 7B in which the containers 713 are transported by the container transporting robot 706 while each inner edge of the containers 713 is hanged with hooks of the container transporting robot 706 from above. Alternatively, the containers 713 may be transported while each side of the containers is caught with the container transporting robot 706.

Note that the containers 713 set in the container setting turntable 707 may be heated with a built-in heater to the temperature which does not disperse the material during the vacuum evacuation. This allows to reduce the heating time after displacement of the containers, thereby providing a device having superior throughput.

The present invention having the foregoing structure will hereinafter be described in more detail in the following embodiments. However, the invention is not limited to the embodiments.

Embodiment 1

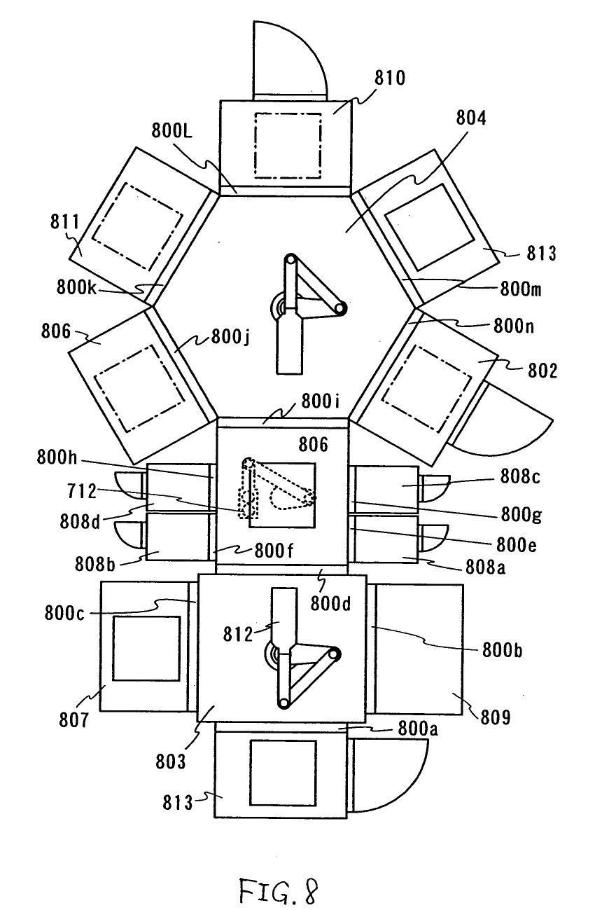

FIG. 8 shows a top view of a multichamber manufacturing device. The manufacturing device as depicted in FIG. 8 comprises chambers arranged for the purpose of improving the throughput.

The multi-chamber manufacturing device in FIG. 8 comprises: shutters 800a to 800n; a substrate loading chamber 801; a sealing and taking-out chamber 802; transporting chambers 803 and 804; film formation chambers 805, 806, and 807; container installation chambers 808a to 808d; a pretreatment chamber 809; a sealing-substrate-loading chamber 810; and a sealing chamber 811.

Hereinafter described is a process for fabricating a light emitting device by delivering a substrate on which an anode (a first electrode) and an insulator (a partition wall) for covering edges of the anode are previously provided, into a manufacturing device shown in FIG. 8. Note that in the case of manufacturing an active matrix light emitting device, a substrate is previously provided with a plurality of thin film transistors (current controlling TFTs) connected to the anode, other thin film transistors (such as a switching TFTs), and a driver circuit formed of thin film transistors. Further, a passive matrix light emitting device can be fabricated by the manufacturing device shown in FIG. 8.

Firstly, the substrate is set in the substrate loading chamber 801. The substrate can be in sizes of 320 mm×400 mm, 370 mm×470 mm, 550 mm×650 mm, 600 mm×720 mm, 680 mm×880 mm, 1,000 mm×1,200 mm, and 1,100 mm×1,250 mm. Furthermore, a substrate as large as 1,150×1,300 mm is applicable.

The substrate (the substrate provided with the anode and the insulator for covering the edges of the anode) set in the substrate loading chamber 801 is transported into the transporting chamber 803. The transporting chamber 803 has a vacuum evacuation means and a transporting mechanism (such as a delivery robot) for delivering or inverting the substrate, and the other transporting chamber 804 has a vacuum evacuation means and a transporting mechanism as well. The robot provided in the transporting chamber 803 can invert the substrate and deliver the inverted substrate into the film formation chamber 805. Further, the transporting chamber 803 can keep its inside under atmospheric pressure or vacuum. The transporting chamber 803 is connected to the vacuum evacuation chamber, and the transporting chamber 803 is capable of being vacuumed by vacuum evacuation or being under atmospheric pressure by introducing inert gas after vacuum evacuation.

The above-described vacuum evacuation chamber has a magnetic levitation turbomolecular pump, a cryopump, or a dry pump. The pumps allow a vacuum level of the transporting chambers connected to respective chambers to be reach to 10⁻⁵ to 10⁻⁶ Pa. Also, reverse diffusion of impurities from the pumps and the evacuation system can be prevented. In order to prevent impurities outside the device from introducing into the device, inert gas such as nitrogen and noble gas is used. As for the gas introduced into the device, a gas, which is highly purified by a gas refining machine prior to being brought into the device, is used. Accordingly, a gas refining machine is required to keep the highly purified gas before it is brought into the vapor deposition apparatus. In this way, oxygen, moisture, and other impurities contained in a gas can be removed in advance; therefore these impurities can be prevented from penetrating in the device.

Before setting the substrate in the substrate loading chamber 801, in order to reduce dot defects, the first electrode (anode) is preferably cleaned with a porous sponge (typically a PVA (polyvinyl alcohol) or a nylon sponge and the like) impregnated with a surfactant (alkalescent) so as to remove dusts from a surface thereof. As for a cleaning mechanism, a cleaning apparatus having a roll brush (for example, formed of PVA) which contacts a surface of a substrate such that the roll brush rotates around an axis line parallel to the surface of the substrate may be used, or another cleaning apparatus having a disk brush (for example, made of PVA) which contacts a surface of a substrate such that the disk brush rotates around an axis line perpendicular to the surface of the substrate may be used.

In order to prevent moisture from penetrating into the substrate from the film formation surface of the substrate, vacuum heating is preferably performed just before forming a film including an organic compound. The resultant substrate is transported from the transporting chamber 803 into the pretreatment chamber 809 enabling to perform vacuum heating, wherein the substrate is annealed for the purpose of degassing under vacuum (5×10⁻³ Torr (0.665 Pa) or less and, preferably, in the range of from 10⁻⁴ Torr to 10⁻⁶ Torr) to remove moisture and the other gases contained in the substrate thoroughly. Particularly, when an organic resin film is used as a material of an interlayer insulating film or a partition wall, the organic resin film is likely to absorb moisture and cause degassing depending on the sorts of the material thereof. Therefore, it is effective that the organic resin material be heated at a temperature in the range of from 100° C. to 250° C.; more preferably in the range of from 150° C. to 200° C.; for example, for 30 minutes or more, and then the heated organic resin material be naturally cooled for 30 minutes and vacuum heating be performed for removing absorbed moisture prior to forming a layer containing an organic compound.

Further, in the film formation chamber 807, a hole injecting layer formed of a polymeric material may be formed by ink-jetting, spin coating, or spraying under an atmospheric pressure or in vacuum, if necessary. Further, after applied by the ink-jetting, a film thickness may be made even by a spin coater. Similarly, after applied by the spraying, the film thickness may be made even by a spin coater. Further, the substrate is longitudinally placed, and then a film may be formed on the substrate in vacuum by inkjetting.

For example, polyethylene dioxythiophene/polystyrenesulfonic acid (abbreviated as PEDT/PSS) solution, polyaniline/camphor sulfonic acid (abbreviated as PANI/CSA) solution, PTPDES, Et-PTPDEK, PPBA or the like which acts as the hole injecting layer (anode buffer layer) may be applied over an entire surface of the first electrode (anode) and baked in the film formation chamber 807. Preferably, the processed substrate is baked in the pretreatment chamber 809.

When the hole injecting layer is formed of a polymeric material by coating such as spin coating, flatness is improved whereby coverage and uniformity in thickness of a film to be formed thereon become favorable. Particularly, the film thickness of the light emitting layer becomes uniform, which allows the light emitting layer to emit light uniformly. In this case, it is preferable that, after the hole injecting layer is formed by coating, vacuum heating (100 to 200° C.) be performed on the hole injecting layer by vapor deposition just before forming a film.

For example, after the surface of the first electrode (anode) is cleaned with the sponge, the substrate is transported into the film formation chamber 807 via the substrate loading chamber 801. After the polyethylene dioxythiophene/polystyrenesulfonic acid (PEDT/PSS) solution is applied on the entire surface of the first electrode (anode) with a film thickness of 60 nm by spin coating, the resultant substrate is delivered into the pretreatment chamber 809, pre-baked at 80° C. for 10 minutes, actually baked at 200° C. for one hour, and vacuum heated (170° C. for 30 minutes followed by cooling for 30 minutes) just before vapor deposition. Then, the resultant substrate is delivered into the film formation chamber 805 and a light emitting layer is formed by vapor deposition without being exposed to the atmospheric air. Particularly, in the case where an ITO film is used as an anode material and a surface thereof is uneven or a minute particle is present on the surface thereof, such detrimental influences can be mitigated by making a film thickness of PEDOT/PSS 30 nm or more.

Further, when a film including PEDOT/PSS is formed by spin coating, the film is formed on the entire surface of the substrate. Therefore, it is preferable that the film formed on edge portions, a peripheral portion, a terminal portion, a connecting region between the cathode and a lower wiring and the like is removed selectively. Preferably, in this case, the film including PEDOT/PSS formed on the above-mentioned portions is selectively removed using a mask by means of O₂ ashing or the like. The pretreatment chamber 809 is provided with a plasma generator in which one or a plurality of gases selected from Ar, H, F, and O are excited to generate plasma, thus dry etching is performed. Further, an UV irradiation mechanism may be provided in the pretreatment chamber 809 such that an ultraviolet ray irradiation can be executed for an anode surface treatment.

Thereafter, the substrate is appropriately transported into the film formation chamber 805 which is connected to the transporting chamber 803 by a transporting mechanism 812. Over the transported substrate, a low molecular organic compound to be a hole injecting layer, a hole transporting layer, a light emitting layer, an electron transporting layer, or an electron injecting layer is appropriately formed. By appropriately selecting the EL material, the light emitting element which emits mono-color (specifically white, red, green, or blue color) light as a whole body of the light emitting element can be fabricated.

The film formation is carried out by moving the robot equipped with the evaporation source 712. Containers filled with the EL material can be set in the evaporation source. As for the containers, the containers as described in Embodiment Modes 1 and 2 can be used.

As described in Embodiment Mode 3, the film formation chamber 805 comprises the container installation chambers 808a to 808d in which a plurality of containers filled with the EL material are provided. The containers filled with a necessary material respectively are sequentially transported into the film formation chamber for deposition. The substrate is set with its face down while aligning the position of the evaporation mask with a CCD or the like, and a deposition can selectively be performed by resistive heating deposition. Once the vapor deposition is finished, the substrate is transported into the next transporting chamber.

Subsequently, the substrate is taken out of the film formation chamber 805 by a transporting mechanism set in the transporting chamber 804 and transported into the film formation chamber 806 without being exposed to the atmosphere, and then a cathode (or a protective film) is formed. The cathode is an inorganic film (a film formed by co-depositing aluminum and an alloy such as MgAg, MgIn, CaF₂, LiF, CaN or an element of group 1 or 2 for the periodic table, or a laminated film thereof) formed by resistive heating deposition. The cathode may also be formed by sputtering.

In the case of fabricating a top emission or a dual emission light emitting device, the cathode is preferably transparent or translucent, which is a thin film made of the above-mentioned metal film (1 to 10 nm in thickness) or a laminated film of a thin film made of the above-mentioned metal film (1 to 10 nm in thickness) with a transparent conductive film. In this case, the cathode made of a film comprising the transparent conductive film (for example, ITO (indium oxide-tin oxide alloy), indium oxide-zinc oxide alloy (In₂O₃—ZnO), or zinc oxide (ZnO) and the like) may be formed in the film formation chamber 806 by sputtering.

A light emitting element having a laminated structure is fabricated by the above-described steps.

Further, the substrate is transported into the film formation chamber 806 connected to the transporting chamber 804, and a protective film made of a silicon nitride film or a silicon nitride oxide film may be formed for sealing. In this case, a target comprising silicon or a target comprising silicon oxide, or a target comprising silicon nitride is provided in the film formation chamber 806. Further, a protective film may be formed by moving a bar-shaped target relative to the fixed substrate. Alternatively, a protective film may be formed by moving the substrate relative to the fixed bar-shaped target.

For example, a silicon nitride film can be formed on the cathode with use of a diskform target formed of silicon by making the atmosphere inside the film formation chamber a nitride atmosphere or an atmosphere including nitride and argon. Further, a carbon-based thin film (such as a DLC (diamond like carbon) film, a CN film, and an amorphous carbon film) may be formed as the protective film, and a chamber for CVD may be provided additionally. The diamond-like carbon film (also referred to as a DLC film) can be formed by plasma CVD, (typically, RF plasma CVD, microwave CVD, electron cyclotron resonance (ECR) CVD, or hot filament CVD), combustion-flame, sputtering, ion beam deposition, or laser deposition. As a reaction gas used for deposition, hydrogen gas and hydrocarbon gas (for example, CH₄, C₂H₂, or C₆H₆) are used. The gases are ionized with glow discharge, and ions are accelerated to a collision with a cathode to which negative self-bias is applied to perform the deposition. Further, the CN film may be formed by using C₂H₄ gas and N₂ gas as the reaction gas. Still further, the DLC film or the CN film is a transparent or translucent insulating film against visible light. The term “transparent against visible light” used herein indicates that the transmittance of the visible light is in the range from 80 to 100% while the term “translucent against visible light” used herein indicates that the transmittance of the visible light is in the range of from 50 to 80%.

Next, the substrate with the light emitting element formed thereon is transported into a sealing and taking-out chamber 802 from the transporting chamber 804.

A sealing substrate is set in the sealing-substrate-loading chamber 810 from outside. Preferably, the sealing substrate is annealed with vacuum in advance in order to remove impurities such as moisture. In the case of forming a sealing member on the sealing substrate for bonding the sealing substrate and the substrate with the light emitting element formed thereon, the sealing member is formed in the sealing chamber 811 and the sealing substrate on which the sealing member is formed is delivered into a sealing-substrate-stock chamber 813. A drying agent may be provided for the sealing substrate in the sealing chamber 811. An evaporation mask may be stocked in the sealing-substrate-stock chamber 813. Although the example of forming the sealing member on the sealing substrate is shown here, the invention is not exclusively limited to this structure and a sealing member may be formed on the substrate with the light emitting element formed thereon.

Next, the substrate and the sealing substrate are adhered to each other in the sealing and taking-out chamber 802 and UV light is irradiated to a bonded pair of substrates with an ultraviolet light irradiation mechanism provided in the sealing and taking-out chamber 802 to cure the sealing member. Note that ultraviolet light curable resin is used as the sealing member here; however, the present invention is not specifically limited thereto as long as the sealing member is an adhesive.

Then, the bonded pair of substrates is taken out of the sealing and taking-out chamber 802.

As described above, by using the manufacturing device shown in FIG. 8, the light emitting element is not exposed to the atmospheric air perfectly until sealed hermetically; therefore the highly reliable light emitting device can be fabricated. Further, vapor deposition is performed by moving the evaporation source and transporting the substrate in the film formation chamber 805, and hence, the deposition can be finished in short times and a light emitting device can be fabricated with a high throughput.

Although not shown in the figure, such systems are provided as a control system for controlling the operation in each chamber, a control system for transporting the substrate between each of the chambers, and a control system for automation by controlling the delivery paths of the substrate between each of the chambers.

In the manufacturing device shown in FIG. 8, a substrate having a transparent conductive film (or a metal film (TiN)) as an anode is transported thereinto, and after forming an layer including an organic compound, a transparent or translucent cathode (for example, a laminated film of a thin metal film (Al, Ag) and a transparent conductive film) is formed, and therefore a top emission (or a dual emission) light emitting element can be formed. Note that the top emission light emitting element is an element, which emits light generated in an organic compound layer by passing through the cathode.

In the manufacturing device shown in FIG. 8 also, a substrate having a transparent conductive film as an anode is delivered thereinto, and after forming the layer including an organic compound, a cathode is formed of a metal film (Al, or Ag), and therefore a bottom emission light emitting element can be formed. Note that the bottom emission light emitting element is an element which emits light generated in an organic compound layer from the anode as a transparent electrode toward a TFT, passing through the substrate.

As set forth above, the manufacturing device of the present invention is applicable to the fabrication for any type of the organic EL element. Further, the manufacturing device allows to perform vapor deposition for a long time, thereby increasing the productivity drastically.

Embodiment 2

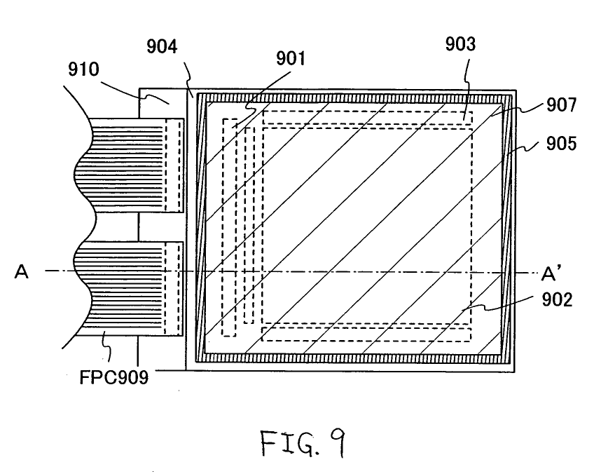

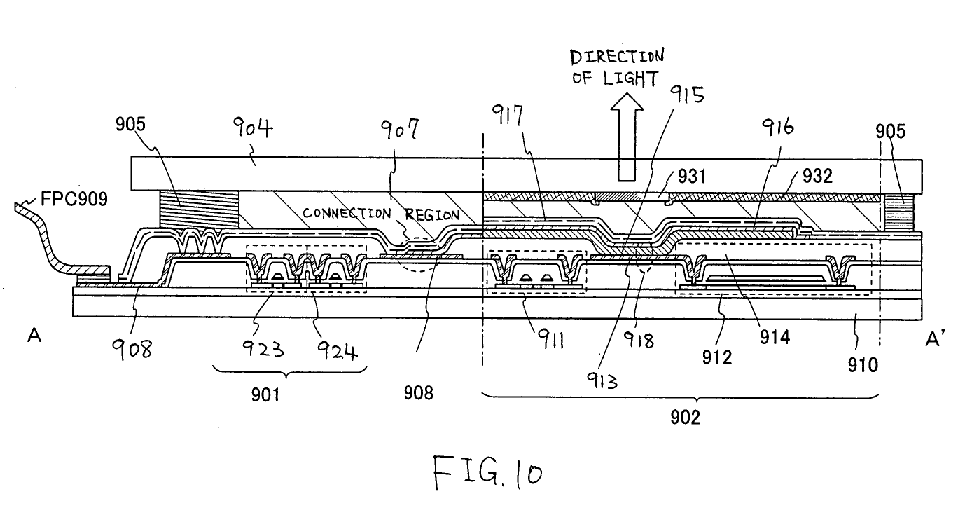

In the present embodiment, FIGS. 9 and 10 show an example where a light emitting device (a top emission structure) having a light emitting element which emits white color light is fabricated on a substrate having an insulated surface. Note that the top emission light emitting structure indicates a structure in which light passes through a substrate opposed to a substrate with the insulated surface.

FIG. 9 is a top view showing the light emitting device whereas FIG. 10 is a cross-sectional view taken along a line A-A′ in FIG. 9. In FIG. 9, reference numeral 901 shown by a dotted line denotes a source signal driving circuit; 902, a pixel portion; 903, a gate signal driving circuit; 904, a transparent sealing substrate; 905, a first sealing member, and a region surrounded by the first sealing member 905 is filled with a transparent second sealing member 907. Note that the first sealing member 905 includes a gap member for keeping the distance between the substrates.

Reference numeral 908 denotes a connection wiring for transmitting a signal inputted into the source signal driving circuit 901 and the gate signal driving circuit 903, and the connection wiring receives video signals and clock signals from an FPC (Flexible Printed Circuit) 909 as an external input terminal. Note that only the FPC is shown here, however, a printed wiring board (PWB) may be provided for this FPC.

A cross-sectional structure is described with reference to FIG. 10. In the drawing, the source signal driving circuit 910 and the pixel portion 902 are formed on a substrate 910.

The source signal driving circuit 901 is composed of a CMOS circuit formed with an n-channel TFT 923 and a p-channel TFT 924. Further, a TFT for constituting the driver circuit may be composed of a known CMOS circuit, PMOS circuit, or NMOS circuit. Moreover, shown in the present embodiment is a driver integrated type where the driver circuit is formed over a substrate, however, the driver circuit can be formed externally as well. The structure of the TFT having a polysilicon layer as an active layer is not particularly limited, and it may be a top gate TFT or a bottom gate TFT.

The pixel portion 902 is formed of a plurality of pixels each of which includes a switching TFT 911, a current controlling TFT 912, and a first electrode (anode) 913 electrically connected to the drain of the current controlling TFT. The current controlling TFT 912 may be an n-channel TFT or a p-channel TFT; however, the current controlling TFT 912 is preferably made of a p-channel TFT in the case of connecting to the anode. Further, it is preferable that a storage capacitor (not shown) be provided appropriately. Note that shown here is a cross-sectional view of only one of the numerous pixels and an example of providing two TFTs in one pixel; however, three or more TFTs may be provided appropriately.

The first electrode (anode) 913 is directly connected to the drain of the TFT; therefore it is preferable that the lower layer of the first electrode (anode) 913 be a material layer which can have an ohmic contact with the drain formed of silicon, and the top layer, which is in contact with the organic compound layer, be a material layer with high work function. The first electrode (anode) desirably has the work function of 4.0 eV or more. For example, in the case where a three-layer structure of a nitride titanium film, an aluminum-based film, and a titanium nitride film is employed, resistance as a wiring is low, a favorable ohmic contact can be obtained, and it can function as an anode. Further, the first electrode (anode) 913 may be a single or a laminated layers of three or more layers of: ITO (indium tin oxide); ITSO composed by mixing 2 to 20% of silicon oxide (SiO₂) with indium oxide; gold (Au); platinum (Pt); nickel (Ni); tungsten (W); chromium (Cr); molybdenum (Mo); iron (Fe); cobalt (Co); copper (Cu); palladium (Pd); zinc (Zn); a Pt film; and nitride metallic material (such as titanium nitride).

Furthermore, an insulator (also referred to as a bank, a partition, a barrier, an embankment and the like) 914 is formed at each end of the first electrode (anode) 913. The insulator 914 may be formed with an organic resin film or an insulating film including silicon. Here, an insulator in a shape as shown in FIG. 10 is formed by using a positive photosensitive acrylic resin film as the insulator 914.

In order to attain a good coverage, an upper edge portion or a lower edge portion of the insulator 914 is preferably curved so as to have a curvature. When the positive photosensitive acrylic resin film is used as a material for the insulator 914, for example, only the upper edge portion of the insulator is curved to have a curvature radius (preferably, 0.2 to 3.0 μm). Either a negative photosensitive material, which becomes insoluble in an etchant under light irradiation or a positive photosensitive material, which becomes soluble in an etchant under light, can be used for the insulator 914.

The insulator 914 may be covered with a protective film formed of an aluminum nitride film, an aluminum oxynitride film, a carbon-based thin film, or a silicon nitride film.

Next, an electroluminescent layer 915 is formed. The electroluminescent layer 915 may be formed of a low molecular weight organic material, a high molecular weight organic material, and an intermediate molecular weight organic material, which has intermediate characteristics of between low and high molecular organic materials. In this embodiment, since the electroluminescent layer 915 is formed by vapor deposition, the low molecular weight organic material is employed. Either the low molecular weight organic material or the high molecular weight organic material is dissolved in a solvent such that these organic materials can be applied by spin coating or ink-jetting. In addition, not only the organic materials but also a complex material of an organic material and an inorganic material can be used.

The electroluminescent layer 915 is selectively formed on the first electrode (anode) 913 by vapor deposition in which the evaporation containers of the invention is used. For example, vapor deposition is performed over the substrate in the film formation chamber as described in Embodiment 1, which is evacuated into a vacuum level up to a degree of 5×10⁻³ Torr (0.665 Pa) or less; preferably, in the range of from 10⁻⁴ Torr to 10⁻⁶ Torr. Upon the vapor deposition process, the organic compound is vaporized in advance by resistive heating, and when a shutter is opened during the vapor deposition, the vaporized organic compound is dispersed in the direction of a substrate. The vaporized organic compound then flies upwardly, and is vapor deposited over the substrate through an opening provided on a metal mask, thereby forming the electroluminescent layer 915 (in which a hole injecting layer, a hole transporting layer, a light emitting layer, an electron transporting layer, and an electron injecting layer are sequentially laminated from the first electrode side). Meanwhile, the electroluminescent layer 915 may not have such laminated structure, and therefore it may have a single layer or a mixed layer structure. Furthermore, a second electrode (cathode) 916 is formed on the electroluminescent layer 915.

By using the evaporation containers and the vapor deposition apparatus according to the invention, the difference in temperature between the opening of the container and the heater can be reduced upon vapor deposition even in the case of a vapor deposition apparatus, which comprises a detachable evaporation source from the heating portion. Therefore, it is possible to prevent the evaporation material from adhering to the opening. Consequently, the number of replacement and maintenance of the evaporation source due to clogging material can be reduced, thereby increasing the throughput. Furthermore, the variation of the evaporation rate can be reduced, thereby providing a light emitting device having high uniform quality.

As for the second electrode (cathode), metals, alloys, compounds having electrical conduction properties, and mixture of these materials, which have small work functions (3.8 eV or less), can be preferably used. As specific examples of the cathode materials, a transition metal containing a rare earth metal can be used, besides an element in the group 1 or 2 for the periodic table, that is, an alkaline metal such as Li, and Cs, alkaline earth metal such as Mg, Ca, and Sr, alloys of these elements (Mg: Ag, Al: Li), or compounds (LiF, CsF, CaF₂). Since the second electrode (cathode) has a light transmitting property, the second electrode can be formed by laminating an extremely thin film made of the above-mentioned metals or an extremely thin alloy including the above-mentioned metals and ITO, IZO, ITOS or the other metals (including the other alloys).

The second electrode (cathode) 916 is formed of a laminated layer of a thin metal film having a small work function and a transparent conductive film (such as ITO, IZO, and ZnO) such that light passes through the substrate. An electroluminescent element 918 including the first electrode (anode) 913, the electroluminescent layer 915, and the second electrode (cathode) 916 is thus formed.

In this embodiment, the electroluminescent layer 915 is formed by sequentially stacking Cu—Pc as a hole injecting layer (20 nm), α-NPD as a first light emitting layer having hole transporting properties (30 nm), CBP+Pt(ppy)acac:15 wt % as a second light emitting layer (20 nm), and BCP as an electron transporting layer (30 nm). Note that, an electron injecting layer (CaF₂) is not necessary in the device since a thin metal film having a small work function is used as the second electrode (cathode).

Thus formed electroluminescent element 918 exhibits white-color emission. Meanwhile, a color filter comprising a coloring layer 931 and a light shielding layer (BM) 932 is provided to realize full color display (for simplification, an over coat layer is not illustrated).

In order to seal the electroluminescent element 918, a transparent protective lamination layer 917 is formed. The transparent protective lamination layer 917 comprises a first inorganic insulating film, a stress relaxation film, and a second inorganic insulating film. As for the first inorganic insulating film and the second inorganic insulating film, such materials formed by sputtering or CVD can be used as: a silicon nitride film; a silicon oxide film; a silicon nitride oxide film (a SiNO film, composition ratio: N>O); a silicon oxynitride film (a SiON film, composition ratio: N<O); and a thin film containing carbon as its main component (for example, a DLC film or a CN film). These inorganic insulating films have high blocking properties against moisture. However, when the film thickness is increased, film stress is also increased; and therefore film peeling is easily occurred.

By interposing a stress relaxation film between the first inorganic insulating film and the second inorganic insulating film, moisture can be absorbed and stress can be relaxed. Even when fine holes (such as pin holes) are generated on the first inorganic insulating film at film formation for any reason, the fine holes can be filled with the stress relaxation film. Also, by forming the second inorganic insulating film on the stress relaxation film, the transparent protective lamination film exhibits excellent blocking properties against moisture or oxygen.

A stress relaxation film is preferably formed of a material having hygroscopic properties with smaller stress than that of the inorganic insulating films. In addition, a material having a light transmitting properties is desirable. As the stress relaxation film, a film containing an organic compound such as α-NPD, BCP, MTDATA, or Alq₃ may be used. These films have hygroscopic properties and are almost light transmitting in case of having thin film thickness. Further, MgO, SrO₂, or SrO can be used as the stress relaxation film since they have hygroscopic properties and light transmitting properties, and can be formed into a thin film by vapor deposition.

In this embodiment, a film formed under an atmosphere containing nitrogen and argon using silicon target, that is, a silicon nitride film having high blocking properties against impurities such as moisture and alkaline metals is used as the first inorganic insulating film or the second inorganic insulating film, whereas a thin Alp₃ film is formed as the stress relaxation film by vapor deposition. Preferably, the total film thickness of the transparent protective lamination layer is formed to be thin as much as possible such that light transmits through the transparent protective lamination layer.

In order to seal the electroluminescent element 918, the sealing substrate 904 is adhered to the substrate 910 with the first sealing agent 905 and the second sealing agent 907 in an inert gas atmosphere. Epoxy resin is preferably used for the first sealing agent 905 and the second sealing agent 907. Desirably, the first sealing agent 905 and the second sealing agent 907 inhibit moisture or oxygen as much as possible.

In this embodiment, as a material for the sealing substrate 904, a plastic substrate formed by FRP (Fiberglass-Reinforced Plastics), PVF (polyvinyl fluoride), polyester, acrylic, and the like can be used besides a glass substrate or a quartz substrate. After pasting the sealing substrate 904 with the first sealing agent 905 and the second sealing agent 907, a third sealing agent may be additionally provided to seal the side surface (exposed surface).

By encapsulating the electroluminescent element 918 with the first sealing agent 905 and the second sealing agent 907, the electroluminescent element 918 can be shielded completely from outside to prevent moisture or oxygen that causes deterioration of the electroluminescent layer 915 from penetrating into the electroluminescent element 918. Consequently, a high reliable light emitting device can be obtained.

When the first electrode (anode) 913 is formed by a transparent conductive film, a dual light emission device, which emits light upwardly and downwardly, can be manufactured.

Embodiment 3

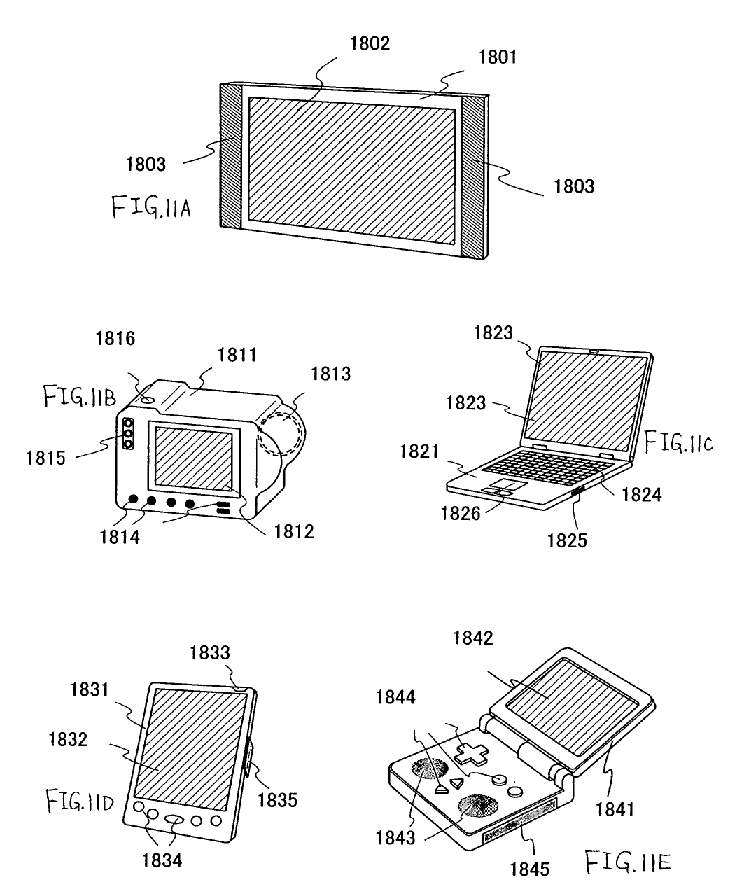

Electronic appliances can be manufactured by applying the present invention. Examples of the electronic appliances include: a video camera; a digital camera; a goggle type display; a navigation system; an audio reproducing apparatus (such as a car audio); a laptop computer; a game machine; a portable information terminal (a mobile computer, a cellular phone, a portable game machine, an electronic book, etc.); and an image reproducing apparatus equipped with a recording medium (specifically, an apparatus capable of reproducing data in a recording medium such as a digital versatile disk (DVD) and having a display that can display the image of the data). Specific examples thereof are shown in FIGS. 11A to 11E.

FIG. 13A shows a display device, which comprises a housing 1801; a display portion 1802; speaker units 1803, etc. The invention can be applied to the display portion 1802. By utilizing the present invention, a display device with a large-size screen can exhibit high quality display without generating display unevenness. The above-mentioned display device includes every display device for displaying information such as one for a personal computer, for receiving TV broadcasting, and for advertisement.

FIG. 11B shows a digital camera, which comprises a main body 1811; a display portion 1812; an image receiving unit 1813; operation keys 1814; an external connection port 1815; a shutter 1816, etc. The invention can be applied to the display portion 1812. By applying the invention to the manufacturing step of the display portion 1812, the digital camera can display images more precisely.

FIG. 11C shows a laptop computer, which comprises a main body 1821; a housing 1822; a display portion 1823; a keyboard 1824; an external connection port 1825; a pointing mouse 1826, etc. The invention can be applied to the display portion 1823. By applying the invention to the display portion 1823, the laptop computer can display images more precisely.

FIG. 11D shows a mobile computer, which comprises a main body 1831; a display portion 1832; a switch 1833; operation keys 1834; an infrared port 1835, etc. The invention can be applied to the display portion 1832. By applying the invention to the display portion 1832, the mobile computer can display images more precisely.

FIG. 11E shows a portable game machine, which comprises a housing 1841; a display portion 1842; speaker units 1843; operation keys 1844; recording medium insertion portion 1845, etc. The invention can be applied to the display portion 1842. By applying the invention to the display device 1842, the portable game machine can display images more precisely.

As set forth above, an application range of the invention is so wide that the invention can be applied to electronic appliances in various fields. Further, even when a large-size substrate with a side of 1 m or more is processed, an evaporation material can be vapor deposited preferably. As a result, the yield of manufacturing products is increased, thereby reducing manufacturing cost for the products ultimately. Furthermore, display quality of products is enhanced according to the invention, and hence, the competitiveness of products can be improved as the electronic appliances enabling to exhibit high quality display.

The present invention has been fully described by way of embodiment modes and embodiments with reference to the accompanying drawings. As has been easily understood by the person skilled in the art, the present invention can be embodied in several forms, and the embodiment modes and its details can be changed and modified without departing from the purpose and scope of the present invention. Accordingly, interpretation of the present invention should not be limited to descriptions mentioned in the foregoing embodiment modes and embodiments.

1. An evaporation container comprising:
a cylindrical body with a bottom filled with an evaporation material; and
a lid including an opening,
wherein an outer edge of the lid protrudes outwardly from the cylindrical body.

2. A container according to claim 1, wherein the lid is detachable.

3. A container according to claim 1, wherein the lid is coated with a material having higher thermal conductivity than that of a material for constituting the lid.

4. A container according to claim 1, wherein the lid is coated with one or more of gold, silver, platinum, copper, aluminum, nickel, beryllium, silicon carbide, carbon nitride, silicon nitride, boron nitride, silicon oxide, beryllium oxide, and aluminum nitride.

5. A container according to claim 1, wherein a material for the evaporation container is selected from tantalum, molybdenum, tungsten, titanium, boron nitride, gold, silver, platinum, copper, aluminum, nickel, beryllium, silicon carbide, silicon nitride, boron nitride, silicon oxide, beryllium oxide, and aluminum nitride.

6. An evaporation container comprising:
a body including a hollow to be filled with an evaporation material; and
a lid including an opening,
wherein an upper part of a side surface for the lid is provided with an accordion-shaped structure.

7. A container according to claim 6, wherein a projection of the accordion-shaped structure for the lid protrudes outwardly from the side surface of the container.

8. A container according to claim 6, wherein the lid is detachable.

9. A container according to claim 6, wherein the lid is coated with a material having higher thermal conductivity than that of a material for constituting the lid.

10. A container according to claim 6, wherein the lid is coated with one or more of gold, silver, platinum, copper, aluminum, nickel, beryllium, silicon carbide, carbon nitride, silicon nitride, boron nitride, silicon oxide, beryllium oxide, and aluminum nitride.

11. A container according to claim 6, wherein a material for the evaporation container is selected from tantalum, molybdenum, tungsten, titanium, boron nitride, gold, silver, platinum, copper, aluminum, nickel, beryllium, silicon carbide, silicon nitride, boron nitride, silicon oxide, beryllium oxide, and aluminum nitride.

12. A vapor deposition apparatus comprising:
an evaporation container including a cylindrical body with a bottom to be filled with an evaporation material, and a lid, the lid including an outer edge protruding outwardly from the body and an opening; and
an evaporation source having a heating portion for heating the evaporation container,
wherein the outer edge of the lid is in contact with the heating portion.

13. An apparatus according to claim 12, wherein diameter of the outer edge for the lid is larger than that of an opening for the evaporation source, and an under surface of the outer edge for the lid is in contact with an upper surface of the heating portion.

14. An apparatus according to claim 12, wherein the lid is detachable.

15. An apparatus according to claim 12, wherein the lid is coated with a material having higher thermal conductivity than that of a material for constituting the lid.

16. An apparatus according to claim 15, wherein the material having higher thermal conductivity is one or more of gold, silver, platinum, copper, aluminum, nickel, beryllium, silicon carbide, carbon nitride, silicon nitride, boron nitride, silicon oxide, beryllium oxide, and aluminum nitride.

17. A vapor deposition apparatus comprising:
an evaporation container including a cylindrical body with a bottom to be filled with an evaporation material, and a lid with an opening; and
an evaporation source having a heating portion for heating the evaporation container,
wherein an upper portion of a side surface for the lid is provided with an accordion-shaped portion.

18. An apparatus according to claim 17, wherein a projection of the accordion-shaped portion for the lid protrudes outwardly from a sidewall of the container.

19. An apparatus according to claim 17, wherein the lid is detachable.

20. An apparatus according to claim 17, wherein the lid is coated with a material having higher thermal conductivity than that of a material for constituting the lid.

21. An apparatus according to claim 20, wherein the material having higher thermal conductivity is one or more of gold, silver, platinum, copper, aluminum, nickel, beryllium, silicon carbide, carbon nitride, silicon nitride, boron nitride, silicon oxide, beryllium oxide, and aluminum nitride.
